(19) United States
(12) Patent Application Publication
(10) Pub. No.: US 2008/0124662 A1
(43) Pub. Date: May 29, 2008

(54) WAFER STAGE MODULE OF TWIN SCAN EXPOSURE SYSTEM AND METHOD OF CONTROLLING THE SAME

(75) Inventor: Se-Jong YU, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/866,343

(22) Filed: Oct. 2, 2007

(30) Foreign Application Priority Data
Nov. 28, 2006 (KR) 2006-0118011

(51) Int. Cl. G03F 7/20; B25B 11/00

(52) U.S. Cl. 430/323; 269/37; 269/45

(57) ABSTRACT

In an embodiment, a wafer stage module comprises: a stage divided into an exposure zone and a measurement zone; a plurality of chucks configured to be respectively moved between the exposure zone and the measurement zone; guides parallel to each other at both edge sides of the wafer stage; a plurality of first sliders slideably disposed along the plurality of guides; a plurality of beams vertically connecting the plurality of first sliders; and a pair of second sliders formed on each of the plurality of beams, for holding and moving each of the plurality of chucks and for swapping the plurality of chucks without moving on each of the plurality of beams, thus avoiding a travel time of the chucks.

### CROSS-REFERENCE TO RELATED APPLICATION

This application claims the benefit of Korean Patent Application No. 10-2006-0118011, filed Nov. 28, 2006, the disclosure of which is hereby incorporated herein by reference in its entirety.

### BACKGROUND

1. Technical Field

Some embodiments of the present invention relate to exposure equipment, and more particularly, to a wafer stage module of a twin scan exposure system, which includes a measurement zone for measuring the center position or a predetermined position of a wafer, and an exposure zone for exposing a photoresist formed on the wafer to light by using a position measured in the measurement zone.

2. Discussion of the Related Art

In semiconductor device fabrication processes, an exposure process emits a light onto photoresist coated on a wafer, to transfer a circuit pattern of a mask to be formed on the wafer. Conventional exposure equipment for performing the exposure process uses a single wafer chuck or wafer table. However, ASML, a lithography equipment manufacturer, has developed the twin scan exposure system that uses two wafer chucks.

The principle of the twin scan exposure system is to simultaneously perform an exposure of a wafer while measuring another wafer. That is, while performing an exposure process on a wafer positioned on a first wafer chuck in a first zone (hereinafter, referred to as ‘exposure zone’), the center position or a predetermined position of a wafer loaded on a second wafer chuck is measured in a second zone (hereinafter, referred to as ‘measurement zone’). Then, in a form of position swapping, the first wafer chuck may be positioned in the measurement zone and the second wafer chuck may be positioned in the exposure zone. In the measurement zone, a new wafer may then be loaded, and the wafer previously completing the exposure process in the exposure zone may be unloaded. Since this twin scan mode performs a wafer position measurement process and an exposure process side by side, the measurement process being performed prior to the exposure process, productivity is greatly improved.

In the wafer stage of the twin scan exposure system, the exposure zone and the measurement zone are separated. Therefore, when the exposure process is completed, it is necessary to swap the first wafer chuck and the second wafer chuck between the exposure zone and the measurement zone. The wafer chuck swapping process in the twin scan exposure system is disclosed in detail in U.S. Pat. No. 6,498,350.

A conventional wafer stage module of a twin scan exposure system will be described with reference to the drawings.

FIGS. 1A, 1B, 1C, and 1D are plan views schematically illustrating the operation of the conventional wafer stage module of the twin scan exposure system.

In FIG. 1A, when a first wafer chuck 40 is positioned in an exposure zone 32, an exposure process of a first wafer 10a loaded on the first wafer chuck 40 is performed. Simultaneously, when a second wafer chuck 50 is positioned in a measurement zone 34, a measurement process of the center position or a predetermined position of a second wafer 10b is performed. Prior to the present second wafer 10b, a previous wafer already having completed the exposure process was unloaded from the second wafer chuck 50 and the new present second wafer 10b was subsequently loaded onto the second wafer chuck 50 in the measurement zone 34.

In a wafer stage 30, Y-sliders 46 and 56 are configured to move along parallel Y-guides 45, each Y-guide 45 disposed at both side edges of the wafer stage 30 oriented in a Y-direction. Using the Y-sliders 46 and 56 and the Y-guides 45, the first wafer chuck 40 and the second wafer chuck 50 may be moved in the Y-direction. X-beams 42 and 52 are oriented in an X-direction to bridge from one Y-guide 45 to the other. The X-beams 42 and 52 are supported by the Y-sliders 46 and 56. X-sliders 44 and 54 are configured to move along the X-beams 42 and 52 to move the first wafer chuck 40 and the second wafer chuck 50 in the X-direction. The combination of the Y-sliders 46 and 56 and the X-sliders 44 and 54 allow complete movement of the first and second wafer chucks 40 and 50 in the X-Y plane.

The exposure zone 32, as shown in FIGS. 1A through 1D, is in the right portion of the wafer stage 30, and the measurement zone 34 is in the left portion. Because of this arrangement, starting now, the Y-sliders 46 are named the exposure Y-sliders 46; the Y-sliders 56 are named the measurement Y-sliders 56; the X-slider 44 is named the exposure X-slider 44; the X-slider 54 is named the measurement X-slider 54; the X-beam 42 is named the exposure X-beam 42; and the X-beam 52 is named the measurement X-beam 52.

The first wafer chuck 40 and the second wafer chuck 50 are respectively held by an exposure connection unit 48 and a measurement connection unit 58, which are respectively positioned on the exposure X-slider 44 and the measurement X-slider 54. Reference number 60 indicates cable shuttles.

In FIG. 1B, the first wafer chuck 40, which supports the first wafer 10a completing the exposure process, and the second wafer chuck 50, which supports the second wafer 10b completing the position measurement process, are moved towards the middle of the wafer stage 30, along the Y-guides by the Y-sliders 45 and 56. When the first and the second wafer chucks 40 and 50 arrive at a swap position in the middle of the wafer stage 30, the exposure and the measurement connection units 48 and 58 disconnect from the first and the second wafers 10a and 10b, respectively.

In FIG. 1C, after the exposure X-slider 44 is moved up in the plane that includes the exposure X-beam 42 (in the direction of the arrow as shown), the exposure connection unit 48 of the exposure X-slider 44 connects to the second wafer chuck 50. Simultaneously, after the measurement X-slider 54 is moved down in the plane of the measurement X-beam 52 (in the direction of the arrow as shown), the measurement connection unit 58 of the measurement X-slider 54 connects to the first wafer chuck 40. The exposure X-slider 44 and the measurement X-slider 54 are then moved in directions opposite to each other, completing a swapping of the first wafer chuck 40 and the second chuck 50.

In this conventional wafer stage module process, during the swap of the first wafer chuck 40 and the second wafer chuck 50, the exposure X-slider 44 and the measurement X-slider 54 have to be moved in parallel in directions opposite to each other. This swapping process will be discussed further below.

In FIG. 1D, as the exposure Y-sliders 46 and the measurement Y-sliders 56 become more distant from each other, the first wafer chuck 40 is moved to the measurement zone 34 and the second wafer chuck 50 is moved to the exposure zone 32. Thus, the first wafer 10a, having completed the exposure process, is unloaded from the first wafer chuck 40 after arriving in the measurement zone 34. Then another first wafer 10a, to be subject to a new exposure process, is loaded in the first wafer chuck 40, so that a measurement process of the center position or a predetermined position of the new wafer can be performed. Simultaneously, an exposure process is performed on the second wafer 10b that is loaded on the second wafer chuck 50, after arriving in the exposure zone 32.

Although the conventional wafer stage module of the twin scan exposure system can greatly improve manufacturing productivity compared to older systems, there is still room for improvement. For instance, when swapping the first wafer chuck 40 and the second wafer chuck 50, it takes time for the exposure X-slider 44 and the measurement X-slider 54 to return to their respective positions along the exposure X-beam 42 and the measurement X-beam 52. This travel time reduces productivity.

### SUMMARY OF EMBODIMENTS

Therefore, the present invention is directed to provide a wafer stage module of a twin scan exposure system, which increases or maximizes productivity by removing a travel time for X-sliders during a wafer chuck swap. The present invention is also directed to a method of controlling the wafer stage module of the twin scan exposure system.

In an aspect of the present invention there is provided a wafer stage module of a twin scan exposure system, comprising:

a stage divided into a first zone and a second zone; chucks configured to respectively move between the first zone and the second zone; a pair of parallel guides, one of the pair on each side edge of the stage; first sliders slideably attached to the pair of parallel guides; beams connecting one of the first sliders on one of the pair of parallel guides to another one of the first sliders on the other one of the pair of parallel guides, the beams configured to respectively move in the first zone and the second zone; and a pair of second sliders slideably disposed on each of the beams, configured to hold and move the chucks in the first zone and the second zone and configured to swap the chucks without moving on the beams.

In another aspect of the present invention, there is provided a method of operating a wafer stage module of a twin scan exposure system that includes an exposure zone and a measurement zone separated in a Y direction, first and second exposure X-sliders slideably disposed in the exposure zone, and first and second measurement X-sliders slideably disposed in the measurement zone, the method comprising: using the first exposure X-slider to hold a first chuck; performing an exposure process with the first chuck in the exposure zone; using the second measurement X-slider to hold a second chuck; performing a measurement process with the second chuck in the measurement zone; after the exposure process and the measurement process are completed, positioning the first chuck and the second chuck at a boundary between the exposure zone and the measurement zone; transferring the first chuck from the first exposure X-slider to the first measurement X-slider; transferring the second chuck from the second measurement X-slider to the second exposure X-slider; and moving the first chuck to the measurement zone and the second chuck to the exposure zone.

### BRIEF DESCRIPTION OF THE DRAWINGS

The above and other features and advantages of the present invention will become more apparent to those of ordinary skill in the art by describing in detail preferred embodiment thereof with reference to the attached drawings in which:

FIGS. 1A through 1D are plan views schematically illustrating an operation of a conventional wafer stage module of a twin scan exposure system;

FIG. 2 is a plan view schematically illustrating a wafer stage module of a twin scan exposure system according to an embodiment of the present invention; and

FIGS. 3A through 3C are plan view sequentially illustrating an operation of the wafer stage module of the twin scan exposure system according to the illustrated embodiment of the present invention.

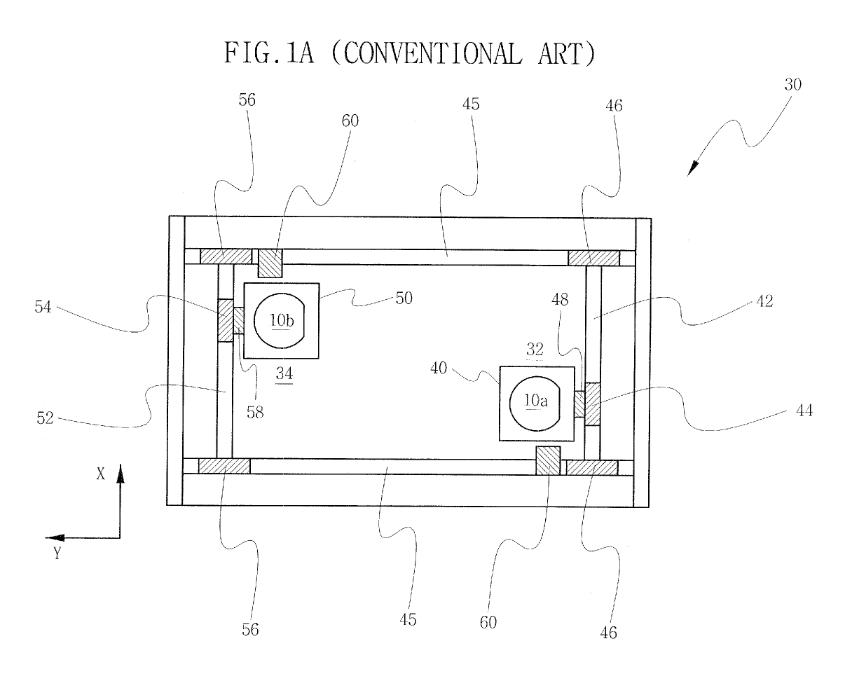

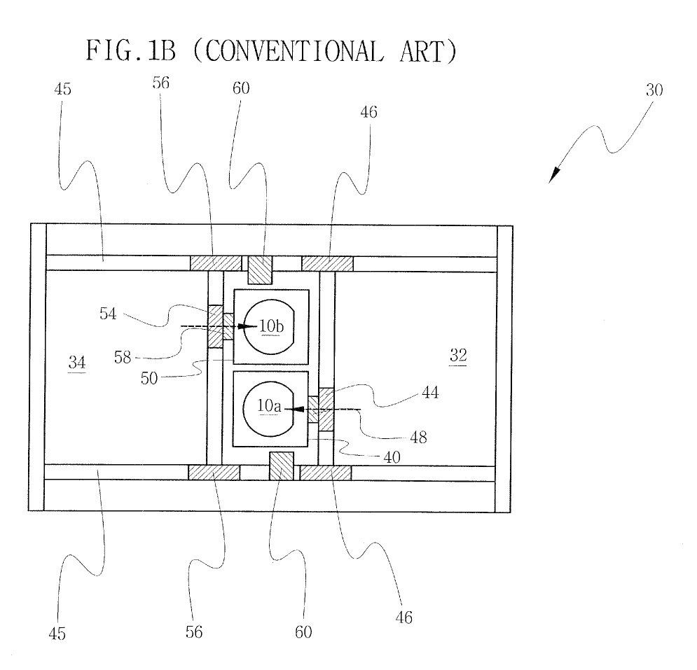

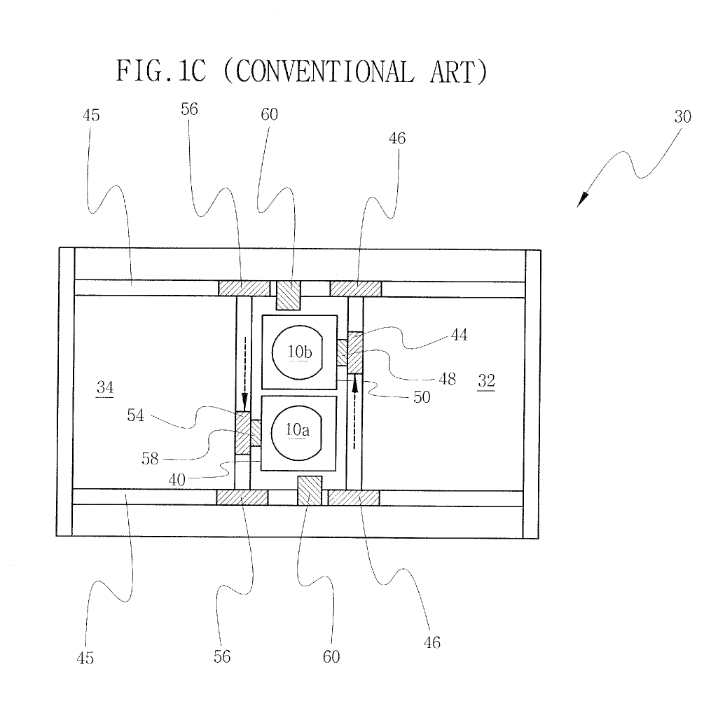

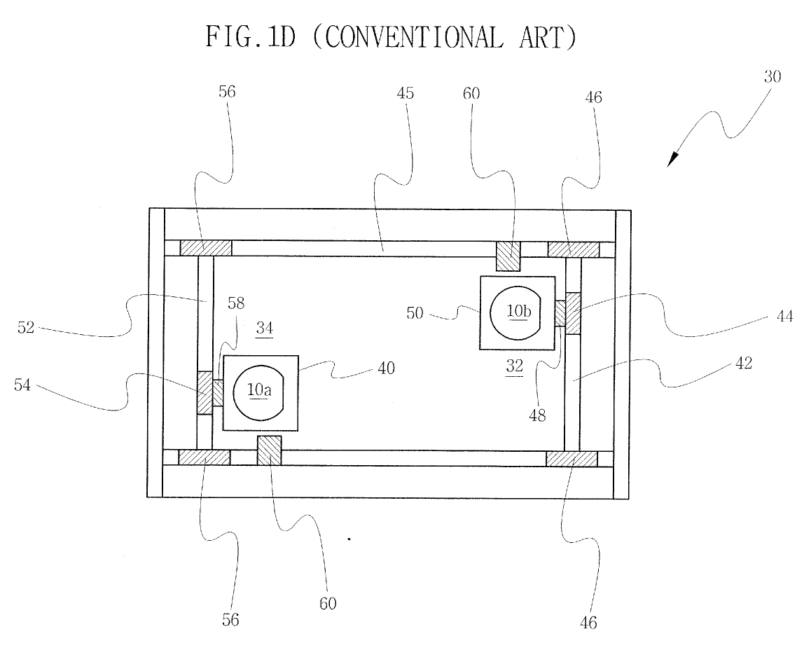

### DETAILED DESCRIPTION OF SOME EMBODIMENTS

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

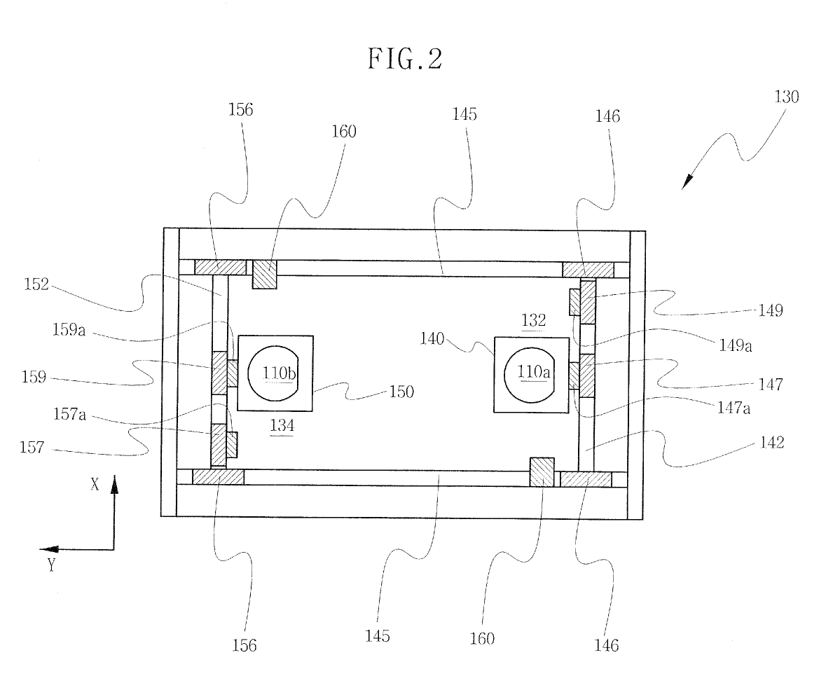

FIG. 2 is a plan view schematically illustrating a wafer stage module of a twin scan exposure system according to an embodiment of the present invention.

As illustrated in FIG. 2, the wafer stage module of the twin scan exposure system comprises: a wafer stage 130, a first wafer chuck 140 and a second wafer chuck 150, a plurality of Y-guides 145, a plurality of exposure Y-sliders 146 and a plurality of measurement Y-sliders 156, an exposure X-beam 142 (a first X-beam) and a measurement X-beam 152 (a second X-beam), a pair of a first exposure X-slider 147 and a second exposure X-slider 149, and a pair of a first measurement X-slider 157 and a second measurement X-slider 159. The wafer stage 130 is divided into an exposure zone 132 in a right-hand portion and a measurement zone 134 in a left-hand portion, as shown in the figures. The first wafer chuck 140 and the second wafer chuck 150 may be moved between the exposure zone 132 and the measurement zone 134 in the wafer stage 130. The Y-guides 145 are parallel to each other, disposed at both side edges of the wafer stage 130, aligned to transit between the exposure zone 132 and the measurement zone 134. A pair of the exposure Y-sliders 146 are each at opposite ends of the exposure X-beam in the exposure zone 132. And a pair of the measurement Y-sliders 156 are each at opposite ends of the measurement X-beam in the measurement zone 134. The exposure Y-sliders 146 and the measurement Y-sliders 156 may be linearly moved along the Y-guides 145. The exposure X-beam 142 and the measurement X-beam 152 connect the two exposure Y-sliders 146 to each other and connect the two measurement Y-sliders 156 to each other. The pair of the first and second exposure X-sliders 147 and 149 is formed on the exposure X-beam 142, to movably hold the first wafer chuck 140 and the second wafer chuck 150 in the exposure zone 132 and to swap the first wafer chuck 140 and the second wafer chuck 150 without needing to move the wafer chucks 140 and 150 along the exposure X-beam 142. Similarly, the pair of the first measurement X-slider 157 and the second measurement X-slider 159 is formed on the measurement X-beam 152, to movably hold the first wafer chuck 140 and the second wafer chuck 150 in the measurement zone 134 and to swap the first wafer chuck 140 and the second wafer chuck 150 without needing to move the wafer chucks 140 and 150 along the measurement X-beam 152.

The wafer stage 130 is configured so that the first wafer chuck 140 and the second wafer chuck 150 are moved horizontally, while a vertical motion is not required during a wafer chuck swap. Thus, any corresponding travel time is avoided.

As known in the art, a vibration isolation stage (not shown) may be included with the wafer stage 130. Further, the wafer stage 130 may be formed in a predetermined shape for receiving the first wafer chuck 140 and the second wafer chuck 150 and allowing the first wafer chuck 140 and the second wafer chuck 150 to freely moved in the exposure zone 132 and the measurement zone 134. For example, the wafer stage 130 may be formed in a rectangular shape with the Y-axis of a Cartesian coordinate system, shown in FIG. 2, in the length direction and the X-axis thereof in the width direction. The first wafer chuck 140 and the second wafer chuck 150 may be moved in the X-Y plane. An exposure apparatus (not shown) may be positioned on the wafer stage 130 in the exposure zone 132 to allow light to be perpendicularly incident on the wafer. The light may shine on a photoresist formed on the wafer for a photolithographic process, for example. A measurement apparatus (not shown) may be positioned on the wafer stage 130 in the measurement zone 134, to measure the center position or a predetermined position of a wafer. Further, a wafer handler (not shown) may be positioned at a side of the wafer stage 130 adjacent to the measurement zone 134, to unload or load a first wafer 110a or a second wafer 110b from or onto the first wafer chuck 140 or the second wafer chuck 150.

The first wafer chuck 140 and the second wafer chuck 150 respectively support the first wafer 110a and the second wafer 110b horizontally and hold the first wafer 110a and the second wafer 110b with a predetermined adhesion force. The first wafer chuck 140 and the second wafer chuck 150 may be connected to a vacuum tube (not shown) and a pneumatic tube (not shown) under or inside the wafer stage 130. A predetermined vacuum pressure provided by the vacuum tube adheres the first wafer 110a and the second wafer 110b loaded on the first wafer chuck 140 and the second wafer chuck 150, respectively at a predetermined adhesion force. A predetermined pneumatic pressure provided by the pneumatic tube allows the first wafer chuck 140 and the second wafer chuck 150 to rise above the inner horizontal plane of the wafer stage 130 at a predetermined height. Then, when the first wafer chuck 140 and the second wafer chuck 150 are rotated in one direction on the wafer stage 130 so that their seats are interchanged, the vacuum tube and the pneumatic tube may be twisted. Therefore, the first wafer chuck 140 and the second wafer chuck 150 may perform their seat change only in their respective divided position. For example, the first wafer chuck 140 may be moved in position within only a predetermined site on the wafer stage 130. And the second wafer chuck 150 may be moved in position within the predetermined site. Therefore, the first wafer chuck 140 and the second wafer chuck 150 may be freely moved in position in their respective X direction but are restricted to move in position within only the defined seats.

The Y-guides 145 in conjunction with the exposure Y-sliders 146 and the Y-guides 145 in conjunction with the measurement Y-sliders 156 allow the first wafer chuck 140 and the second wafer chuck 150 to be moved in the Y direction. Then, the Y-guides 145 and the exposure Y-sliders 146 and the measurement Y-sliders 156 may correspond to a stator and a mover, respectively, of a linear electric motor, for example. The linear electric motor has a different structure from a rotary electric motor having a fixed primary coil and a rotational secondary coil. In the case of the linear electric motor, the exposure Y-sliders 146 and the measurement Y-sliders 156 may be referred to as first sliders that are moved on the Y-guides 145. (The linear electric motor may be thought of as having a flat plate shape into which a rotor part and a stator part of a rotary electric motor are cut in their respective radius directions and are opened. The linear electric motor may be considered as a part being cut from the circumferential direction of the rotary electric motor with an infinite radius. From this view, the linear electric motor does not differ from the rotary electric motor in principle.)

Linear electric motor types include a synchronous type (corresponding to a synchronous motor or direct current motor of the rotary electric motor) and non-synchronous type (corresponding to an inductor electric motor of the rotary electric motor). The structures of the linear electric motors are diverse. The synchronous linear motor is used for an exposure process that requires accurate control. In the synchronous linear motor, when a fixed magnetized magnetic pole is included in the stator part and alternating power is sent to an armature of the mover part, an electromagnetic force acts between the stator and the mover. For a driving force in one direction, it is necessary to continuously detect the polarity of the magnetic pole and change the direction of the current corresponding to the magnetic pole. Speed control is performed by synchronizing speed and continuously changing the frequency. Therefore, the stator magnetic pole is formed in the Y-guides 145 and the armature to which the power with a predetermined frequency is supplied is formed in the exposure Y-sliders 146 and the measurement Y-sliders 156. Then, when the equal power is applied to the exposure Y-sliders 146 which are moved along the Y-guides 145, the exposure X-beam 142 is moved in the Y direction.

Likewise, the exposure X-beam 142, the first exposure X-slider 147 and the second exposure X-slider 149 may also be formed to respectively correspond to a stator and mover of a linear electric motor. The measurement X-beam 152, the first measurement X-slider 157, and the second measurement X-slider 159 may also be formed in the same manner. Both ends of the exposure X-beam 142 and both ends of the measurement X-beam 152 are respectively supported by the exposure Y-sliders 146 and the measurement Y-sliders 156 so that the exposure X-beam 142 and the measurement X-beam 152 may be moved in the Y direction. Therefore, the exposure X-beam 142 and the measurement X-beam 152 may move the first wafer chuck 140 and the second wafer chuck 150 in the Y direction. The exposure X-sliders may be restrained by the exposure X-beam 142 and selectively hold the first wafer chuck 140 or the second wafer chuck 150. The first exposure X-slider 147 and the second exposure X-slider 149 respectively include a first exposure connection part 147a and a second exposure connection part 149a which have the same structure to hold the first wafer chuck 140 or the second wafer chuck 150 in an inward direction towards the middle (the middle of the Y-guides 145 or the boundary between the exposure zone 132 and the measurement zone 134) of the wafer stage 130, as shown in the embodiment of FIG. 2. For example, the first exposure connection part 147a and the second exposure connection part 149a may respectively include a clamp to mechanically hold an arbitrary, but perhaps predetermined, structure formed on a side of the first wafer chuck 140 and the second wafer chuck 150. The first exposure connection part 147a and the second exposure connection part 149a formed on the exposure X-sliders perform operations opposite to each other at the same time during a swapping of the first wafer chuck 140 and the second wafer chuck 150. When the first exposure connection part 147a releases the first wafer chuck 140, the second exposure connection part 149a takes hold of the second wafer chuck 150.

Further, the first measurement X-slider 157 and the second measurement X-slider 159 may be restrained by the measurement X-beam 152 and selectively hold the first wafer chuck 140 or the second wafer chuck 150. The first measurement X-slider 157 and the second measurement X-slider 159 may respectively include a first measurement connection part 157a and a second measurement connection part 159a, which may have the same structure to hold the first wafer chuck 140 or the second wafer chuck 150 in an inward direction towards the middle (the middle of the Y-guides 145 or the boundary between the exposure zone 132 and the measurement zone 134) of the wafer stage 130. The first measurement connection part 157a and the second measurement connection part 159a may be operated by the same principle of the first exposure connection part 147a and the second exposure connection part 149a. Reference numeral 160 indicates cable shuttles.

The first and second exposure X-sliders 147 and 149 may be moved in the X direction along the exposure X-beam 142 in the exposure zone 132. The first and second measurement X-sliders 157 and 159 may be moved in the X direction along the measurement X-beam 152 in the measurement zone 134.

When the first exposure X-slider 147 holds the first wafer chuck 140, the first measurement X-slider 157, which is opposite to the first exposure X-slider 147, cannot hold the second wafer chuck 150 because the first measurement X-slider 157 needs to receive the first wafer chuck 140 during a transfer when swapping with the first wafer chuck 140, and vice versa. Therefore, when the first exposure X-slider 147 and the second measurement X-slider 159, which are positioned diagonally, or the second exposure X-slider 149 and the first measurement X-slider 157, which are also positioned diagonally, respectively hold the first wafer chuck 140 and the second wafer chuck 150, the exposure process or the measurement process is performed in each zone. Further, the first exposure X-slider 147 and the second measurement X-slider 159 and the first measurement X-slider 157 and the second exposure X-slider 149 are able to swap the first wafer chuck 140 and the second wafer chuck 150 in the middle (or any region near the middle) of the wafer stage 130. Then, the first exposure X-slider 147 and the first measurement X-slider 157 may selectively hold the first wafer chuck 140 in the middle (the middle of the Y-guides 145) of the wafer stage 130 and swap the first wafer chuck 140 without a movement in the X direction during the swap. Likewise, the second exposure X-slider 149 and the second measurement X-slider 159 may selectively hold and swap the second wafer chuck 150 without a movement in the X direction.

Therefore, since the wafer stage module of the twin scan exposure system according to the present embodiment comprises the pair of the first exposure X-slider 147 and the second exposure X-slider 149 and the pair of first measurement X-slider 157 and the second measurement X-slider 159, which are formed on the exposure X-beam 142 and the measurement X-beam 152, respectively, to move the first wafer chuck 140 or the second wafer chuck 150 in the X direction in the wafer stage 130, it removes a travel time for a movement in the X direction when swapping the first wafer chuck 140 and the second wafer chuck 150, thereby increasing or maximizing productivity.

A method of controlling the wafer stage module of the twin scan exposure system according to the above-described embodiment will now be described.

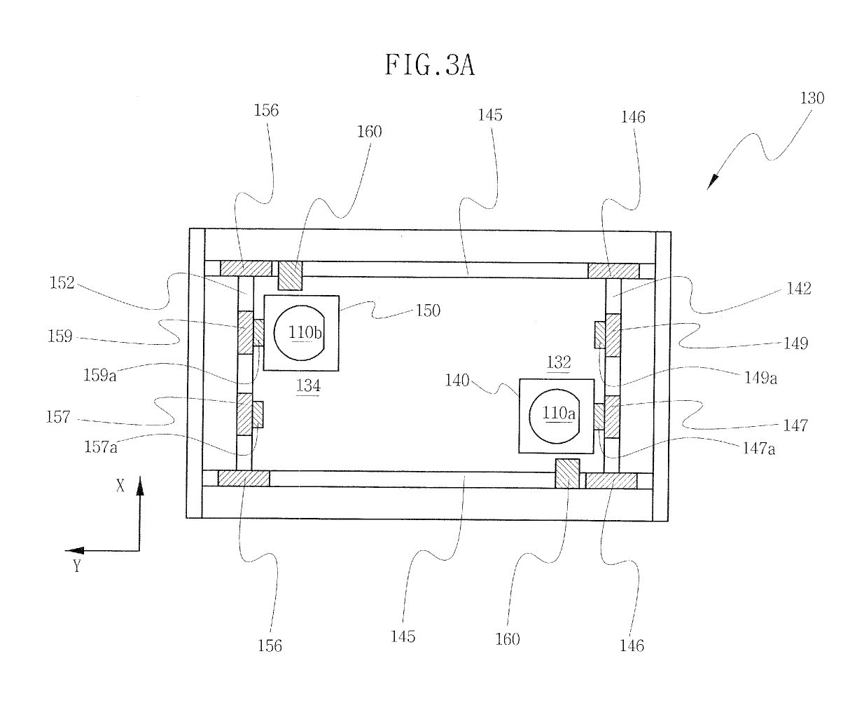

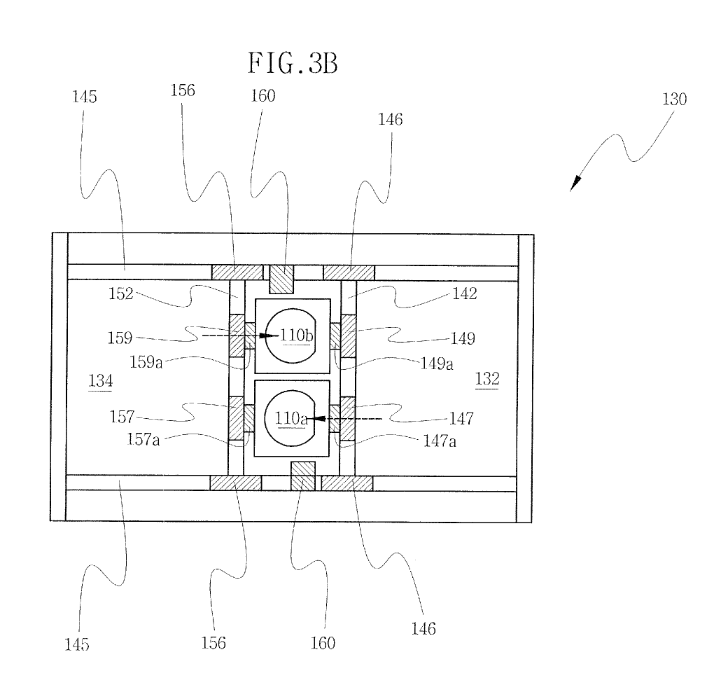

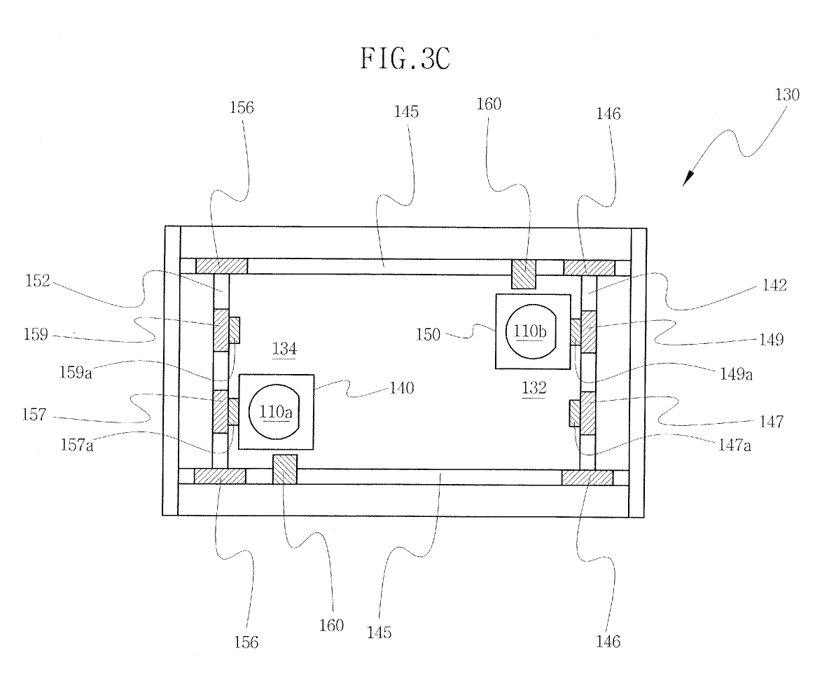

FIGS. 3A through 3C are plan views sequentially illustrating the operation of the wafer stage module of the twin scan exposure system according to the embodiment.

While an exposure process is performed on a wafer loaded on the first wafer chuck 140 positioned in the exposure zone 132, a new wafer is loaded on the second wafer chuck 150 positioned in the measurement zone 134, and the measurement process of measuring the center position or predetermined position of the new wafer is performed. The first wafer chuck 140 is moved in the X direction by the first exposure X-slider 147 on the exposure X-beam 142 and is moved in the Y direction by the exposure Y-sliders 146. For example, the exposure process may include exposing a photoresist formed on the wafer to light by a scanning method, to correspond to a predetermined pattern. The exposure process takes more time than the measurement process. When the first exposure X-slider 147 holds the first wafer chuck 140 and the exposure process is performed on the first wafer 110a loaded on the first wafer chuck 140, the second exposure X-slider 149 is positioned at one edge of the exposure X-beam 142 so as not to obstruct the movement of the first exposure X-slider 147. Subsequently, when the exposure process of the first wafer 110a is completed, the second exposure X-slider 149 is positioned on the same line as the second measurement X-slider 159 in the X direction, to receive the second wafer chuck 150 that will be transferred from the second measurement X-slider 159. The second wafer chuck 150 is moved in the X and/or Y directions by the second measurement X-slider 159 and the measurement Y-sliders 156. Then, the wafer completing the exposure process is unloaded from the first wafer chuck 140. Before a new exposure process is performed on a new wafer, the center position or a predetermined position of the new wafer may be measured. At the same time, a new exposure process is carried out. Further, when the second measurement X-slider 159 holds the second wafer chuck 150 and the measurement process is performed on the second wafer 110b loaded on the second wafer chuck 150, the first measurement X-slider 157 is positioned at the other edge side of the measurement X-beam 152 so as not to obstruct the movement of the second measurement X-slider 157. Subsequently, when the measurement process of the second wafer 110b is completed, the first measurement X-slider 157 is positioned on the same line as the first exposure X-slider 147 in the X direction, to receive the first wafer chuck 140 being transferred from the first exposure X-slider 147. That is, when the exposure process and the measurement process of the first wafer 110a and the second wafer 110b are completed, the first exposure X-slider 147 and the first measurement X-slider 157 are positioned to be opposite to each other with the first wafer chuck 140 centered between, and the second measurement X-slider 159 and the second exposure X-slider 149 are positioned to be opposite to each other with the second wafer chuck 150 center between. Subsequently, the first wafer chuck 140 and the second wafer chuck 150 are positioned in the middle (the middle of the Y-guides 145 or the boundary between the exposure zone 132 and the measurement zone 134, for example) of the wafer stage 130.

As illustrated in FIG. 3B, the first wafer chuck 140, which loads the wafer completing the exposure process, and the second wafer chuck 150, which loads the wafer completing the measurement process are moved to the middle (the middle of the Y-guides 145) of the wafer stage 130. When the first wafer chuck 140 and the second wafer chuck 150 arrive at a swap position, the first exposure connection part 147a of the first exposure X-slider 147 releases the first wafer chuck 140, and the second exposure connection part 149a of the second exposure X-slider 149 takes hold of the second wafer chuck 150. Simultaneously, the second measurement connection part 159a of the second measurement X-slider 159 releases the second wafer chuck 150, and the first measurement connection part 157a of the first measurement X-slider 157 takes hold of the first wafer chuck 140. Then, the first exposure X-slider 147 and the second measurement X-slider 159, while not being moved in the X direction, respectively transfer the first wafer chuck 140 and the second wafer chuck 150 to the first measurement X-slider 157 and the second exposure X-slider 149. As mentioned earlier, removing the movement in the X direction and the time required for this movement when swapping the first wafer chuck 140 and the second wafer chuck 150 can increase manufacturing productivity.

As illustrated in FIG. 3C, as the exposure Y-sliders 146 become farther from the measurement Y-sliders 156, the first wafer chuck 140 is moved to the measurement zone 134 and the second wafer chuck 150 is moved to the exposure zone 132. The exposure process is performed on the second wafer loaded on the second wafer chuck 150 as it arrives in the exposure zone 132. Simultaneously, when the first wafer 110a completing the exposure process is unloaded from the first wafer chuck 140 after arriving in the measurement zone 134, and a new first wafer 110a to be subject to the exposure process is loaded on the first wafer chuck 140, the measurement process for measuring the center position or a predetermined position of the wafer is performed on the new first wafer 110a. The first wafer 110a may be unloaded from or loaded onto the first wafer chuck 140 by a wafer handler (not shown) adjacent to the measurement zone 134. Further, the measurement process may measure position coordinates of the center of the wafer from the center of the first wafer chuck 140 and may reset the center position of the wafer as the origin of the coordinates. Therefore, the first wafer chuck 140 may be moved in the X direction in the measurement zone 134 and the exposure zone 132 by the first measurement X-slider 157 and the first exposure X-slider 147, so that the measurement process and the exposure process of the first wafer 110a loaded on the first wafer chuck 140 are performed. The second wafer chuck 150 may be moved in the X direction in the measurement zone 134 and the exposure zone 132 by the second measurement X-slider 159 and the second exposure X-slider 149, so that the measurement process and the exposure process of the second wafer 110b loaded on the second wafer chuck 150 are performed. Then, the first wafer chuck 140 is positioned in one of the measurement zone 134 and the exposure zone 132 and the second wafer chuck 150 is positioned in the other of those zones.

When the measurement process of the first wafer 110a loaded on the first wafer chuck 140 is completed and the exposure process of the second wafer 110b loaded on the second wafer chuck 150 is completed, the Y-sliders 146 and 156 position the first wafer chuck 140 and the second wafer chuck 150 at the boundary between a first zone (not shown) and a second zone (not shown) in the Y direction. Then, the first measurement X-slider 157 releases the first wafer chuck 140 without moving in the X direction, and the first exposure X-slider 147 holds the first wafer chuck 140 to be moved to the exposure zone 132. Simultaneously, the second exposure X-slider 149 releases the second wafer chuck 150, and the second measurement X-slider 159 takes hold of the second wafer chuck 150 to be moved to the measurement zone 134.

Consequently, since the wafer stage module of the twin scan exposure system according to the embodiment of the present invention swaps the first wafer chuck 140 by using the first exposure X-slider 147 and the first measurement X-slider 157 and swaps the second wafer chuck 150 by using the second exposure X-slider 149 and the second measurement X-slider 159, it does not need the movement in the X direction when swapping the first wafer chuck 140 and the second wafer chuck 150 between the exposure zone 132 and the measurement zone 134.

As described above, since the wafer stage module of the twin scan exposure system according to the present invention comprises a pair of exposure X-sliders formed in an exposure X-beam, and a pair of measurement X-sliders formed in an exposure X-beam, to move the first wafer chuck or the second wafer chuck in the X direction within the wafer stage, it does not need travel time for the movement of the X-sliders when swapping the first wafer chuck and the second wafer chuck, thereby increasing or maximizing manufacturing productivity.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A wafer stage module of a twin scan exposure system, comprising:
a stage having X and Y axes, the stage divided into a first zone and a second zone;
a plurality of chucks;
a pair of guides parallel to the Y axis, one of the pair on each side edge of the stage;
a plurality of Y-sliders slideably attached to the pair of parallel guides;
a plurality of beams connecting one of the Y-sliders on one of the pair of parallel guides to another one of the Y-sliders on the other one of the pair of parallel guides, the beams configured to respectively move in the first zone and the second zone; and
a pair of X-sliders slideably disposed on each of the beams, configured to hold the chucks and to swap the chucks between the first zone and the second zone without moving the chucks on the beams.

2. The wafer stage module according to claim 1, wherein the first zone is an exposure zone and the second zone is a measurement zone, the pair of guides extend between the exposure zone and the measurement zone in the Y direction, and the beams comprise a first X-beam and a second X-beam that are aligned in the X direction.

3. The wafer stage module according to claim 2, wherein the X-sliders comprise:
a first exposure X-slider and a second exposure X-slider, which are slideably attached to the first X-beam; and
a first measurement X-slider and a second measurement X-slider, which are slideably attached to the second X-beam.

4. The wafer stage module according to claim 3, wherein the plurality of chucks comprise:
a first chuck configured to move in the first zone and the second zone by the first exposure X-slider and the first measurement X-slider; and
a second chuck configured to move in the first zone and the second zone by the second exposure X-slider and the second measurement X-slider.

5. The wafer stage module according to claim 4, wherein the first exposure X-slider and the first measurement X-slider respectively comprise a first exposure connection part and a first measurement connection part to hold the first chuck, and the second exposure X-slider and the second measurement X-slider respectively comprise a second exposure connection part and a second measurement connection part to hold the second chuck.

6. The wafer stage module according to claim 5, wherein the first exposure connection part is configured to release the first chuck while the first measurement connection part takes hold of the first chuck without a movement of the first exposure X-slider and the first measurement X-slider.

7. The wafer stage module according to claim 5, wherein the second measurement connection part is configured to release the second chuck while the second exposure connection part takes hold of the second chuck without a movement of the second exposure X-slider and the second measurement X-slider.

8. The wafer stage module according to claim 5, wherein the first measurement connection part is configured to release the first chuck while the first exposure connection part takes hold of the first chuck without a movement of the first exposure X-slider and the first measurement X-slider.

9. The wafer stage module according to claim 5, wherein the second exposure connection part is configured to release the second chuck while the second measurement connection part takes hold of the second chuck without a movement of the second exposure X-slider and the second measurement X-slider.

10. An apparatus for handling wafer chucks comprising:
a pair of parallel guides mounted for movement toward and away from one another;
a first chuck holder on each guide mounted for sliding movement along the guide, the chuck holder being constructed and arranged to detachably secure a wafer chuck thereto; and
a second chuck holder on each guide mounted for sliding movement along the guide, the second check holder being constructed and arranged to receive a wafer chuck held by the opposing first chuck holder and detachably secure the wafer chuck to the second chuck holder when the chuck is released from the first chuck holder.

11. The apparatus of claim 10, further comprising a measurement region for measuring wafers and an exposure region for performing photolithography.

12. The apparatus of claim 10, wherein the apparatus includes a twin scan exposure system to simultaneously perform an exposure of a wafer while measuring another wafer.

13. A method of changing a first configuration in which a first chuck is slidable along a first guide in a pair of parallel guides and a second chuck is slidable along the second guide in the pair to a second configuration in which the first chuck is slidable along the second guide and the second chuck is slidable along the first guide, the method comprising:
positioning a pair of chuck holders on each of the guides;
securing the first chuck to a chuck holder on the first guide and the second chuck to a chuck holder on the second guide so that each chuck is opposite a free chuck holder on the other guide;
moving the guides toward one another until each chuck is adjacent the opposing free chuck holder;
detaching each chuck from its chuck holder; and
attaching each chuck to its associated opposing chuck holder.

14. The apparatus of claim 13, further comprising performing an exposure of a wafer mounted on one of the chucks while measuring another wafer mounted on the other chuck.
